(19) United States
(12) Patent Application Publication
(10) Pub. No.: US 2013/0147575 A1
(43) Pub. Date: Jun. 13, 2013

(54) CAPACITIVE BONDING STRUCTURE FOR ELECTRONIC DEVICES

(71) Applicants: Eric S. LI, Taipei (TW); Yu-Shao Shiao, Hsinchu (TW); Tzi-Hong Chiueh, Taipei (TW); Shu-Yang Chen, Taipei (TW)

(72) Inventors: Eric S. LI, Taipei (TW); Yu-Shao Shiao, Hsinchu (TW); Tzi-Hong Chiueh, Taipei (TW); Shu-Yang Chen, Taipei (TW)

(73) Assignee: NATIONAL TAIPEI UNIVERSITY OF TECHNOLOGY, Taipei (TW)

(21) Appl. No.: 13/610,962

(22) Filed: Sep. 12, 2012

(30) Foreign Application Priority Data
Dec. 9, 2011 (TW) 100145554

(51) Int. Cl. H03H 7/38

(52) U.S. Cl. 333/32

(57) ABSTRACT

A bonding structure is applied to electrically connect a chip and a circuit board, such as a micro-strip line, for signal transmission between each other. The bonding structure includes a metallic plate and a capacitor. The chip and the micro-strip line are placed on the metallic plate but do not overlap or contact with each other. In particular, the capacitor is used to connect a signal pad of the chip and a signal line of the micro-strip line for signal transmission at high frequencies.

### BACKGROUND OF THE INVENTION

(1) Field of the Invention

This invention relates to a bonding structure, and particularly to a capacitive bonding structure for high-frequency electronic devices.

(2) Description of the Prior Art

Recently, following the advances in wireless communications technology, the services provided by wireless communications and their close connection to the Internet have made the market of wireless communications booming nowadays. As most wireless products are made of various high-frequency active/passive electronic components, the quality of such electronic components becomes critical. To ensure the quality of these wireless products, the fabrication of these high-frequency electronic components becomes very important.

In order to meet the requirements, a device chip, usually an integrated circuit (IC) chip, is required to be connected to a signal line of a planar transmission line such as a micro-strip line. Conventional techniques to connect a chip to a micro-strip line include the following: the wire-bonding method, the ribbon-bonding method and the flip-chip-bonding method.

The wire-bonding method is the most popular conventional technique because of its low cost. Please refer to FIG. 1, which is a schematic view showing the bonding structure of the conventional wire-bonding method. The bonding structure 100a of the conventional wire-bonding method, which connects a chip 120 to a micro-strip line 130, comprises a metallic plate 110, a chip 120, a micro-strip line 130 with a discontinued signal line 131, a direct current block (DC-block) capacitor 140 and a piece of bonding wire 150a, wherein the said chip 120, which is mounted on the metallic plate 110, has a signal pad 121 used for the connection of wire bonding; the said micro-strip line 130, which is also mounted on the metallic plate 110 but is not in any contact or connection with the chip 120, includes a signal line 131 with a discontinuity 1311, a dielectric layer 132 and a ground plane 133; the said DC-block capacitor 140, which is placed on top of the discontinuity 1311 of the signal line 131 of the micro-strip line 130, serves to connect the discontinued signal line 131; and the said bonding wire 150a, which has a width of a thousandth of an inch (1 mil) and a length of approximate sixty thousandths of an inch (60 mil), makes an electrical connection between the signal pad 121 on the chip 120 and the proximal part of the signal line 131 of the micro-strip line 130. However, the insertion loss caused by the parasitical inductance, which is induced by the bonding wire 150a of approximate 60 mil in length, becomes severe when the bonding structure 100a is operated at high frequencies.

In order to solve the problem of the insertion loss caused by the parasitical inductance induced in the conventional wire-bonding method, the conventional ribbon-bonding method is adopted accordingly. Please refer to FIG, 2, which is a schematic view showing the bonding structure of the conventional ribbon-bonding method. The bonding structure 100b of the conventional ribbon-bonding method comprises a metallic plate 110, a chip 120, a micro-strip line 130 with a discontinued signal line 131, a DC-block capacitor 140 and a ribbon of aluminum strip 150b, wherein the said chip 120, which is mounted on the metallic plate 110, has a signal pad 121 used for the connection of ribbon bonding; the said micro-strip line 130, which is also mounted on the metallic plate 110 but is not in any contact or connection with the chip 120, includes a signal line 131 with a discontinuity 1311, a dielectric layer 132, and a ground plane 133; the said DC-block capacitor 140, which is placed on top of the discontinuity 1311 of the signal line 131 of the micro-strip line 130, serves to connect the discontinued signal line 131; and the said aluminum strip 150b is used here to replace the bonding wire 150a in the previous bonding structure 100a of the conventional wire-bonding method for the purpose of reducing the insertion loss caused by the parasitical inductance induced at higher operating frequencies. However, due to the oversize problem about the width of the aluminum strip in the bonding structure 100b of the conventional ribbon-bonding method, the aluminum strip is poorly connected to the signal pad of the chip 120 and the signal line 131 of the micro-strip line 130 and is liable to fall off from either of them.

In order to solve the problems of the wire-bonding method and the ribbon-bonding method, a lead-tin alloy ball 150c used by the conventional flip-chip-bonding method is used to replace the bonding wire 150a and the aluminum strip 150b of the prior arts to provide the connection between the chip 120 and the micro-strip line 130. Please refer to FIG. 3, which is a schematic view showing the bonding structure of the conventional flip-chip-bonding method. The bonding structure 100c of the conventional flip-chip-bonding method comprises a metallic plate 110, a chip 120, a micro-strip line 130 with a discontinued signal line 131, a DC-block capacitor 140 and a lead-tin alloy ball 150c, wherein the said chip 120, which is flipped over from its regular position in the prior arts, has a signal pad 121 facing down and used for the connection of flip-chip bonding; the said micro-strip line 130, which is mounted on the metallic plate 110 but is not in any contact or connection with the chip 120, includes a signal line 131 with a discontinuity 1311, a dielectric layer 132 and a ground plane 133; the said DC-block capacitor 140, which is placed on top of the discontinuity 1311 of the signal line 131 of the micro-strip line 130, serves to connect the discontinued signal line 131; and the said lead-tin alloy ball 150c, which has a diameter of five thousandths of an inch (5 mil), is closely sandwiched between the signal pad 121 of the chip 120 and the proximal part of the signal line 131 of the micro-strip line 130 in an orderly-stacked manner so that the chip 120 and the micro-strip line 130 are electrically connected. The bonding structure 100c of the conventional flip-chip-bonding method not only can reduce the insertion loss caused by the parasitic inductance, which is induced in the bonding structure 100a of the conventional wire-bonding method, but also can solve the problem of poor connection, which occurs in the bonding structure 100b of the conventional ribbon-bonding method. However, the cost is too much because complicated processes are involved in the fabrication and assembly of the bonding structure 100c.

Concluding from the disclosures heretofore, all three conventional bonding structures inevitably have inherent disadvantages, respectively, though both the wire-bonding method and the ribbon-bonding method have the common advantages of low cost and ease of fabrication while the flip-chip-bonding method has the advantages of low insertion loss at high operating frequencies and good connection between the signal pad 121 of the chip 120 and the signal line 131 of the micro-strip line 130. For the bonding structure 100a of the conventional wire-bonding method, not only an indispensable DC-block capacitor 140 is required to block DC power but also the problem of severe insertion loss caused by the parasitic inductance induced at higher operating frequencies must be solved. For the bonding structure 100b of the conventional ribbon-bonding method, not only an indispensable DC-block capacitor 140 is required to block DC power but also the problem of poor connection between the aluminum strip and either the signal pad 121 of the chip 120 or the signal line 131 of the micro-strip line 130 must be solved. For the bonding structure 100c of the conventional flip-chip-bonding method, not only an indispensable DC-block capacitor 140 is required to block DC power but also a high fabrication cost is expected.

Therefore, how to design a bonding structure featuring low cost, better electrical connection and low insertion loss for signal transmission between the chip 120 and the micro-strip line 130 at high frequencies becomes an important issue in the field of the present invention.

### SUMMARY OF THE INVENTION

The objective of the invention is to present a bonding structure for high-frequency electronic devices, employing a capacitor to provide connection between a chip and a micro-strip line, so as to maintain low insertion loss at higher operating frequencies, and to offer good electrical connection.

In one aspect, the invention provides electronic devices with a capacitive bonding structure, which includes a metallic plate, a chip, a micro-strip line and a capacitor, and is used to electrically connect the chip and the micro-strip line. The chip is mounted on the metallic plate. The micro-strip line, which is also mounted on the metallic plate but is not in any contact or not connection with the chip, has a signal line without any discontinuity. The capacitor serves to electrically connect the signal pad of the chip and the signal line of the micro-strip line.

In an embodiment, the micro-strip line comprises a signal line, a dielectric layer and a ground plane in an orderly-stacked manner such that the dielectric layer is sandwiched between the signal line and the ground plane. The signal line is a metallic strip, and is electrically connected to the signal pad of the chip via the capacitor. The ground plane is a metallic plane, and is placed on the metallic plate. Besides, the capacitor is firmly connected to the signal pad of the chip and the signal line of the micro-strip line via a conductive adhesion method such as soldering.

In an embodiment, the micro-strip line is replaced by a grounded coplanar waveguide or a coplanar waveguide, in which the metallic plate is not needed. In addition, the width of the signal line is determined by the dielectric constant and the thickness of the dielectric layer. The width of the signal line is wide enough for the soldering joint with the corresponding capacitor.

In an embodiment, the range of the capacitance of the capacitor is determined by the operating frequency of the chip. The range of the operating frequency of the capacitor is also determined by the operating frequency of the chip as long as the upper limit of that range of the capacitor is greater than or equal to the operating frequency of the chip.

Compared to the prior arts, the embodiment of the present invention employs the capacitor as a connecting body between the chip and the micro-strip line, so that it has less insertion loss caused by the effects Of the parasitic inductance while operating at high frequencies. In addition, the capacitor has the capability of blocking DC power, so that it can protect other related circuits connected to the capacitive bonding structure. Therefore, no additional DC-block capacitor is required for the micro-strip line as in the prior arts. The present invention can simplify the circuit structure and reduce the cost.

Other objectives and advantages of the present invention will be introduced via more technical features disclosed by the embodiments of the present invention wherein the preferred embodiments of this invention are shown and described simply by the illustrations best suitable to explain the invention.

### BRIEF DESCRIPTION OF THE DRAWINGS

FIG. 1 is a schematic view showing the bonding structure of the conventional wire-bonding method.

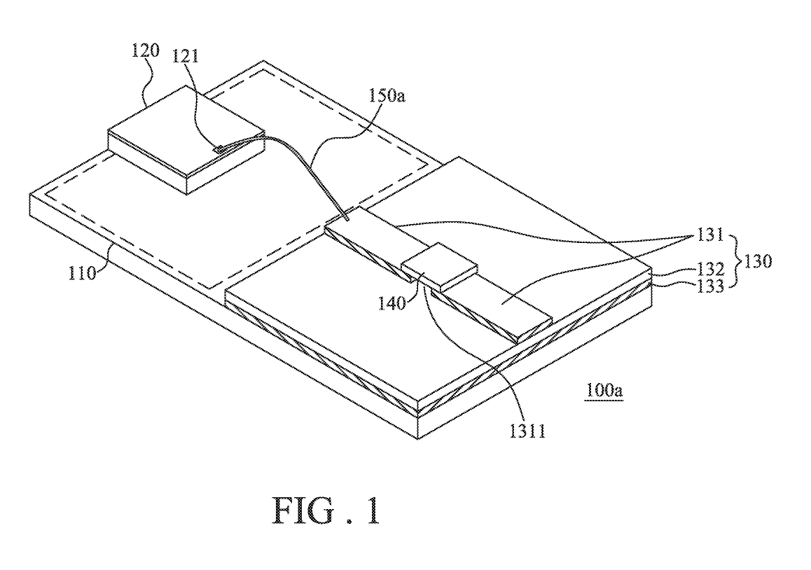

FIG. 2 is a schematic view showing the bonding structure f the conventional ribbon-bonding method.

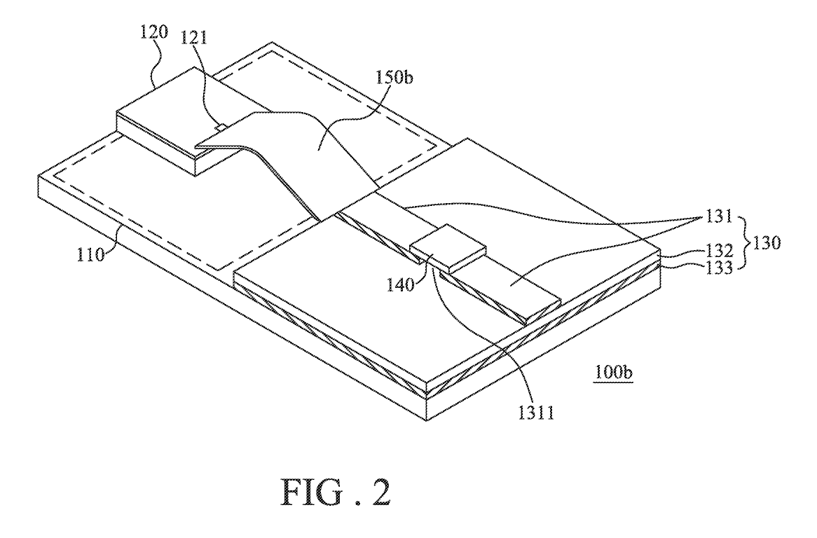

FIG. 3 is a schematic view showing the bonding structure of the conventional flip-chip-bonding method.

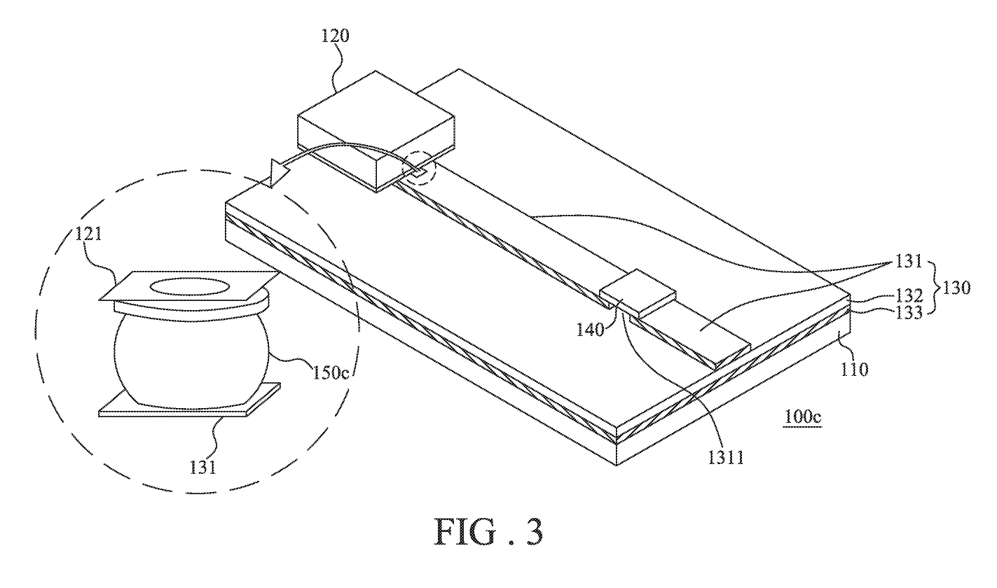

FIG. 4 is a top view showing the bonding structure of the capacitive bonding method for an exemplary embodiment of the present invention.

FIG. 5 is a cross-section view showing a Micro-strip line for an exemplary embodiment of the present invention.

FIG. 6 is a schematic view showing part of the bonding structure of the capacitive bonding method for an exemplary embodiment of the present invention.

FIG. 6A is a cross-section view showing the bonding structure of the capacitive bonding method for an exemplary embodiment of the present invention.

FIG. 7 is a plot comparing the frequency response of an exemplary embodiment of the present invention to the frequency responses of exemplary embodiments of the conventional bonding methods.

### DESCRIPTION OF THE PREFERRED EMBODIMENTS

In the following detailed description of the preferred embodiments, references are made to the accompanying drawings which form a part hereof, and in which the specific embodiments likely to be the realization of the present invention are illustrated. In this regard, terminologies related to direction, such as “top,” “bottom,” “front,” “back,” etc., are used to refer to the orientations of the objects described in the figure(s). The constituents of the present invention can be positioned in a number of different orientations. As such, the terminologies related to direction are used for the purpose of illustration and are in no way of limiting the present invention. On the other hand, the drawings are only schematic plots and the sizes of the constituents may he exaggerated for the purpose of clarity. It is to be understood that other embodiments may be utilized with changes likely made in the structure of the present invention, but do not depart from the scope of the present invention. Also, it is to be understood that the phraseologies and terminologies used herein are for the purpose of describing the present invention and should not be regarded as limiting the present invention. The use of “including,” “comprising,” or “having” and variations thereof herein is meant to encompass the items listed thereafter and the equivalents thereof as well as the additional items. Unless limited, otherwise the terms “connected,” “coupled,” and “mounted” and variations thereof herein are used in a broad sense and encompass direct and indirect connections, couplings, and placing one thing on the top of the other thing. Similarly, the terms “facing,” “faces” and variations thereof herein are used in a broad sense and encompass having one thing directly and indirectly face the other thing, and the term “adjacent to” and variations thereof herein are used in a broad sense and encompass one thing directly and indirectly “adjacent to” the other thing. Therefore, the description of “A” component facing “B” component herein may indicates the situation that “A” component facing “B” component directly or the situation of one or more additional components between “A” component and “B” component. Also, the description of “A” component “adjacent to” “B” component herein may indicates the situation that “A” component is directly “adjacent to” “B” component or the situation of one or more additional components between “A” component and “B” component. Accordingly, the drawings and descriptions will be regarded as being illustrative in nature but not as being restrictive.

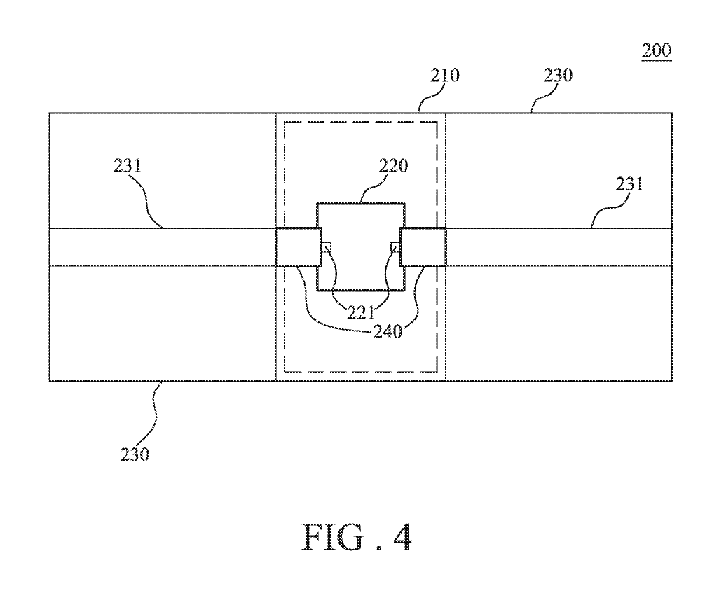

Please refer to FIG. 4, which is a top view showing a capacitive bonding structure for electronic devices in an exemplary embodiment of the present invention. The capacitive bonding structure 200, which is applied to electrically connect a chip 220 to a micro-strip line 230 for signal transmission between each other, further comprises a metallic plate 210 and a pair of capacitors 240 in addition to the chip 220 and the micro-strip line 230, wherein the said chip 220, which is mounted on the top of the central portion of the metallic plate 210, has a pair of signal pads 221 disposed at the two opposite sides of the chip 220, respectively, for ease of connection; the said micro-strip line 230, which is also mounted on the metallic plate 210, has a pair of signal lines 231 with one signal line 231 at one side of the chip 220 and the second line at the opposite side of the chip 220; and each said capacitor 240, which is mounted across the space between the signal pad 221 of the chip 220 and the near signal line 231 of the micro-strip line 230, serves to electrically connect each signal pad 221 of the chip 220 and its corresponding signal line 231 of the micro-strip line 230.

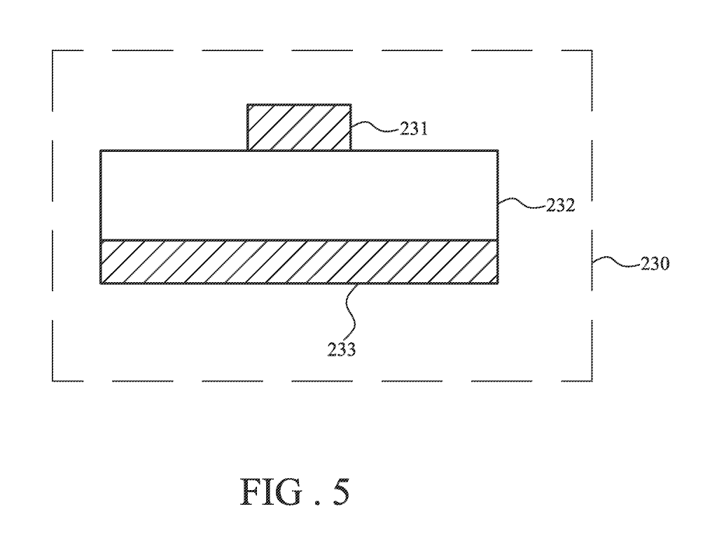

Please refer to FIG. 5, which is a cross-section view showing a micro-strip line for an exemplary embodiment of the present invention. The micro-strip line 130 has a signal line 231, a dielectric layer 232 and a ground plane 233 in an orderly-stacked manner therein such that the dielectric layer 232 is sandwiched between the top signal line 231 and the bottom ground plane 233. The signal line 231 is not in any contact or connection with the central chip 220. In the exemplary embodiments of the present invention, the micro-strip line 230 can he replaced by a grounded coplanar waveguide or a coplanar waveguide, in which the metallic plate 210 is not needed. Regarding the signal line 231 of the micro-strip line 230, the width of the signal line 231 is determined by the dielectric constant and the thickness of the dielectric layer 232 as long as the width of the signal line 231 is wide enough for the soldering joint with the corresponding capacitor 240. Thereby, the micro-strip line 230 has the advantages of simple fabrication process, low cost, good reliability and miniaturization.

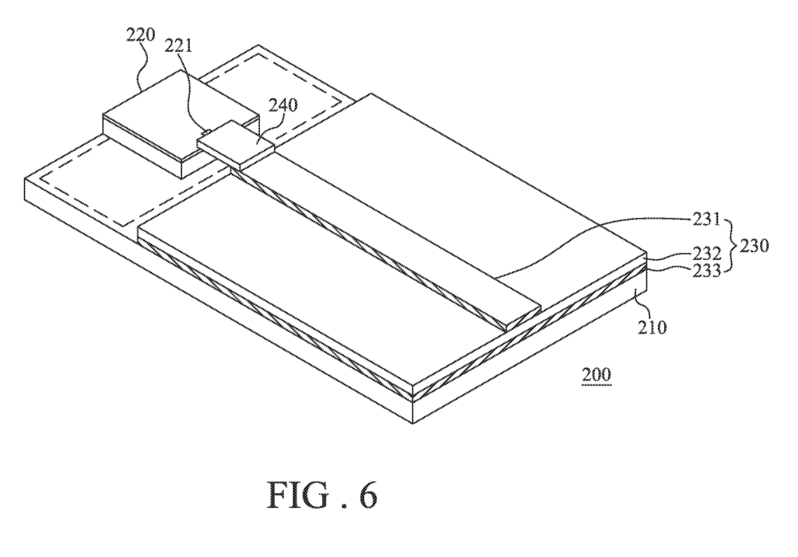

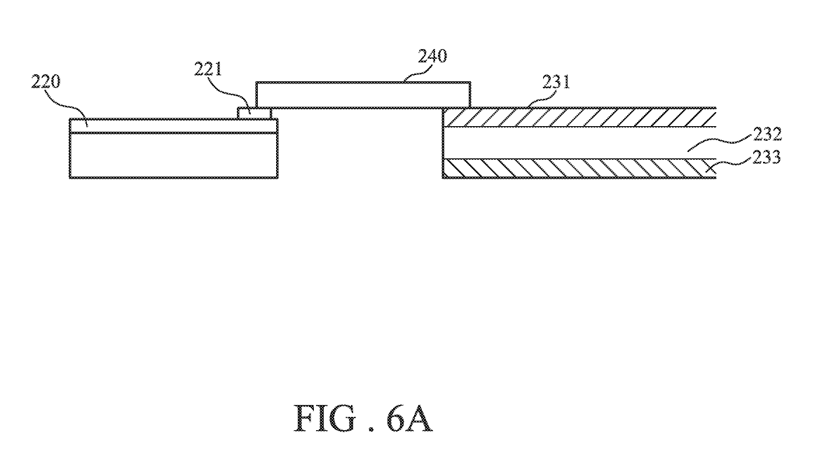

Please refer to FIGS. 6 and 6A, which are a schematic view showing part of the bonding structure of the capacitive bonding method and its cross-section view for an exemplary embodiment of the present invention. In the exemplary embodiment of the present invention, specific types of chip capacitors are adopted for the capacitor 240. The capacitor 240 can be subject to the specifications such as the 0402 specifications or the ones with different dimensions such as the 0603 specifications or the 0201 specifications such that all of foregoing chip capacitors of various specifications can be firmly connected to the signal pad 221 of the chip 220 and the signal line 231 of the micro-strip line 230 via a conductive adhesion method such as soldering. Wherein, the range of the capacitance of the capacitor 240 is determined by the operating frequency of the chip 220. The range of the operating frequency of the capacitor 240 is also determined by the operating frequency of the chip 220 as long as the upper limit of that range of the capacitor is greater than or equal to the operating frequency of the chip.

In a preferred exemplary embodiment of the present invention, the chip capacitors of the 0402 specifications characterized by a length of forty thousandths of an inch (40 mil) and a width of twenty thousandths of an inch (20 mil) are adopted for the capacitor 240 because this type of chip capacitors have been already extensively used in various electronic devices for its low cost. Having the capacitor 240 serve as a connecting body between the signal pad 221 of the chip 220 and the signal line 231 of the micro-strip line 230 can effectively reduce the fabrication cost and simplify the circuit structures of the devices because the capacitor 240 can function as a DC-block capacitor 140 to protect other related circuits connected to the capacitive bonding structure 200 so that no additional DC-block capacitor 140 is required for the micro-strip line 130 to block the DC power as in the prior arts.

For electronic devices employing the wire-bonding structure or the ribbon-bonding structure, parasitic inductance is inevitable at higher operating frequencies due to the length of the connecting body employed by the bonding structure. This parasitic inductance can significantly deteriorate the performance of the electronic devices. Therefore, the present invention employs the capacitor 240 to serve as a connecting body for its capacitive bonding structure between the chip 220 and the micro-strip line 230 to effectively decrease the parasitic inductance by reducing the length of the connecting body.

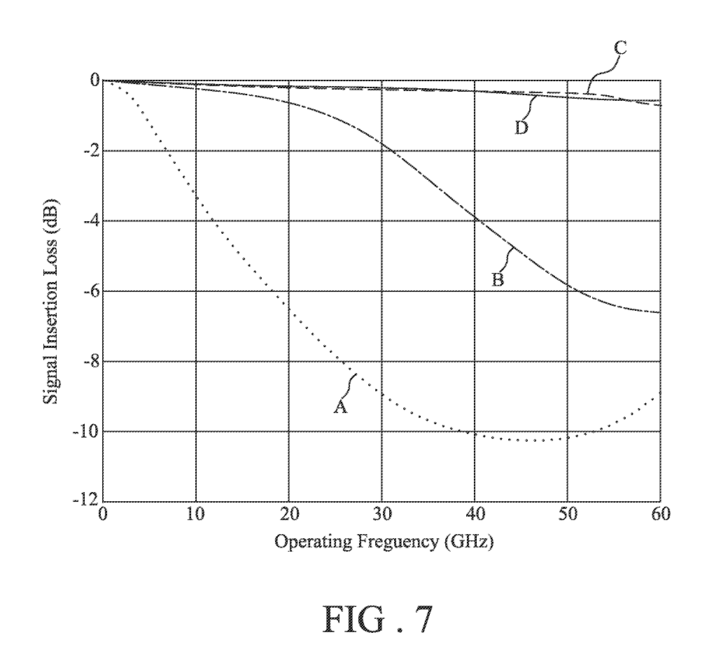

Taking a real exemplary embodiment of the present invention to compare with the exemplary embodiments of the conventional wire-bonding method, ribbon-bonding method and flip-chip-bonding method in terms of their frequency responses, a set of curves are shown in FIG. 7. Wherein, all pertinent parameters of related constituents are expressed as the following. The micro-strip line 230 has a dielectric constant of 3.38, a thickness of 0.2056 millimeter (mm), a length of 3 millimeters (mm), a width of 2.5 millimeters (mm) and a characteristic impedance of 50 ohm (Ω). The signal line 231 of the micro-strip line 230 has a width of 0.44 millimeter (mm). The chip 220 has a length of 1 millimeter (mm), a width of 1 millimeter (mm) and a height of 0.3 millimeter (mm). The signal pad 221 has a length of 80 microns (μm) and a width of 80 microns (μm). A chip capacitor of 0402 specifications is adopted for the capacitor 240, which has a length of 1 millimeter (mm), a width of 0.5 millimeter (mm) and a capacitance of 200 nano Farad (nF).

Please refer to FIG. 7, which compares the frequency response of an exemplary embodiment of the present invention with the frequency responses of the exemplary embodiments of the conventional bonding methods. Wherein, the horizontal coordinate (axis) denotes the operating frequency in Giga Hertz (GHz) while the vertical coordinate (axis) denotes the insertion loss of signal transmission between the chip 220 and the micro-strip line 230 in decibel (dB). Curve A refers to the frequency response of an exemplary embodiment employing the bonding structure of the wire-bonding method. Curve B refers to the frequency response of an exemplary embodiment employing the bonding structure of the ribbon-bonding method, Curve C refers to the frequency response of an exemplary embodiment employing the bonding structure of the flip-chip-bonding method. Curve D refers to the frequency response of an exemplary embodiment employing the capacitive bonding structure of the present invention.

If 1-dB insertion loss is selected to define the bandwidth for signal transmission between the chip 220 and the micro-strip line 230, the following facts are depicted in FIG. 7. The passband of the bonding structure of the wire-bonding method ranges from 0 to 5 Giga Hertz (GHz). The passband of the bonding structure of the ribbon-bonding method ranges from 0 to 25 Giga Hertz (GHz). The passband of the bonding structure of the flip-chip-bonding method ranges from 0 to 60 Giga Hertz (GHz). The passband of the capacitive bonding structure of the present invention ranges from 0 to 60 Giga Hertz (GHz).

Based on the comparison observed in FIG. 7, the following conclusions can be made in terms of the bandwidths of the foregoing bonding structures. The capacitive bonding structure of the present invention has a wide bandwidth up to 60 GHz as opposed to the narrower bandwidths of 5 and 25 GHz offered by the bonding structures of the wire-bonding method and the ribbon-bonding method, respectively. Although both the conventional bonding structure of the flip-chip-bonding method and the capacitive bonding structure of the present invention can offer a wide bandwidth up to 60 GHz, but the fabrication cost of the former is much higher than that of the latter.

To conclude all the disclosures heretofore, the exemplary embodiment of the present invention mentioned above has the following advantages:
1. The capacitive bonding structure of the present invention can offer a low cost in fabrication.
2. The capacitive bonding structure of the present invention features low insertion loss at high operating frequencies and remains good performance.
3. The capacitive bonding structure of the present invention can provide reliable electrical connections. The capacitor is not liable to fall from the connection joints to fail the bonding structure.
4. The capacitive bonding structure of the present invention has an inherent DC-block capability so that no additional DC-block capacitor is required for the micro-strip line to protect the circuits connected to the capacitive bonding structure. Thus, the cost is reduced and the circuit structure is simplified.

The foregoing descriptions of the preferred embodiments of the invention has been presented for the purpose of illustration and explanation. It is not intended to be exclusive or to confine the present invention to the precise form or to the disclosed exemplary embodiments. Accordingly, the foregoing descriptions should be regarded as being illustrative rather than being restrictive. Modifications and variations made to the preferred embodiments should be covered bar the scope of the present invention. The embodiments are chosen and described in order to best explain the principles of the present invention and its best mode for practical applications, thereby to enable persons skilled in the art to understand that the present invention implemented by various embodiments and with various modifications is suitable for the particular use or implementation. It is intended that the scope of the present invention be defined by the claims appended hereto and their equivalents in which all terms are meant in their broadest reasonable sense unless otherwise indicated. Therefore, the terms “the invention”, “the present invention” or the like are not necessarily to confine the scope define by the claims to a specific embodiment, and references to the particularly preferred exemplary embodiments of the invention do not imply a limitation on the present invention, and no such limitation is to be inferred. The invention is limited only by the spirit and scope of the appended claims. The abstract and headline of the disclosure is provided to comply with the rules :for the purpose of conducting survey on patent documents and should not he used to interpret or to confine the scope or meaning of the claims, Any advantages and benefits described hereto may not apply to all the embodiments of the present invention. It should be appreciated that variations made to the embodiments described by persons skilled in the art should not depart from the scope of the present invention as defined by the following claims. Moreover, no element and component in the present disclosure is intended to be dedicated to the public regardless of whether the element or component is explicitly recited in the following claims.

What is claimed is:

1. A capacitive bonding structure for electronic devices, applied to electrically connect a chip having a signal pad and a micro-strip line having a signal line for signal transmission between each other, the capacitive bonding structure comprising:
a metallic plate, for the chip to be mounted thereon;
a micro-strip line, mounted on the metallic plate, with no direct contact and no direct connection to the chip, and having the signal line to be connected to the signal pad of the chip; and
a capacitor, serving to electrically connect the signal pad of the chip and the signal line of the micro-strip line.

2. The capacitive bonding structure of claim 1 for electronic devices, wherein the micro-strip line comprises the signal line, a dielectric layer and a ground plane in an orderly-stacked manner therein such that the dielectric layer is sandwiched between the signal line and the ground plane.

3. The capacitive bonding structure of claim 1 for electronic devices, wherein the signal line is made of a metallic strip, and serves to be electrically connected to the signal pad of the chip via the capacitor.

4. The capacitive bonding structure of claim 2 for electronic devices, wherein the ground plane is made of a metallic plane, and is placed on the metallic plate.

5. The capacitive bonding structure of claim 2 for electronic devices, wherein the dielectric layer has a dielectric constant and a thickness, and the width of the signal line is determined by the dielectric constant and the thickness of the dielectric layer.

6. The capacitive bonding structure of claim 1 for electronic devices, wherein the capacitor is firmly connected to the signal pad and the signal line for good electrical connection via a conductive adhesion method such as soldering.

7. The capacitive bonding structure of claim 1 for electronic devices, wherein the micro-strip line is replaced by a grounded coplanar waveguide line or a coplanar waveguide line, which does not need the metallic plate.

8. The capacitive bonding structure of claim 1 for electronic devices, wherein one type of chip capacitors is selected for the capacitor.

9. The capacitive bonding structure of claim 1 for electronic devices, wherein the capacitance range of the capacitor is determined by the operating frequency of the chip.

10. The capacitive bonding structure of claim 1 for electronic devices, wherein the operating frequency range of the capacitor is determined by the operating frequency of the chip as long as the upper limit of that range of the capacitor is greater than or equal to the operating frequency of the chip.
